(19) United States
(12) Patent Application Publication
(10) Pub. No.: US 2024/0281045 A1
(43) Pub. Date: Aug. 22, 2024

(54) Voltage Droop Monitor

(71) Applicant: Meta Platforms Technologies, LLC, Menlo Park, CA (US)

(72) Inventor: Saurabh Kumar, Portland, OR (US)

(21) Appl. No.: 18/170,864

(22) Filed: Feb. 17, 2023

(51) Int. Cl. H03K 3/037; H03K 3/012; H03K 5/135

(52) U.S. Cl. CPC H03K 3/0372; H03K 3/012; H03K 5/135

(57) ABSTRACT

A voltage droop monitor comprises an error detection circuit comprising a flip-flop, a latch, and a comparator configured to compare a first output of the flip-flop and a second output of the latch. A clock generator is configured to generate a flip-flop clock signal for the flip-flop and a latch clock signal for the latch based on a system clock signal, wherein the flip-flop clock signal and the latch clock signal are inverted and time-shifted with respect to each other, and wherein a triggering edge of the flip-flop clock is configured to occur after a termination of a triggering level of the latch clock signal. A pulse generator circuit is configured to generate a series of pulses. A data path connects an output of the pulse generator circuit to inputs of the flip-flop and the latch, the data path comprising one or more timing delay components.

### TECHNICAL FIELD

This disclosure generally relates to systems and methods for detecting voltage droop in circuits.

### BACKGROUND

Power Delivery Network (PDN) noise is an issue for high-workload integrated circuits. When a large current is needed due to sudden changes in activity, the voltage may drop suddenly. If the voltage of the supply rails drops below a certain threshold, it can result in timing failures in digital timing paths, thereby leading to errors. To combat this, conventional integrated circuits add voltage margins at the top of the DC supply voltage to ensure zero timing failures even when voltage droop occurs. For example, a 3.5V supply may be used even though only 3V is needed. While this is a simple solution, it comes with a heavy power penalty, since the voltage margin added results in higher leakage and higher dynamic power consumption even when the voltage margin is not needed.

### SUMMARY OF PARTICULAR EMBODIMENTS

Techniques described herein address the aforementioned problem using a voltage droop monitor to eliminate the need for a voltage margin or reduce the magnitude of a voltage margin that would otherwise be needed. Embodiments described herein provide a droop detection and mitigation mechanism that can actively monitor voltage droops and generate error signals quickly to trigger one or more mitigation plans.

Particular embodiments are directed to an all-digital voltage droop detector circuit that can actively monitor the supply rail voltage noise and dynamically generate the error/warning signals to trigger droop mitigation plans. In particular embodiments, the droop detection latency is less than one system clock cycle so that droop detection and error generation could be triggered before a droop causes system failure errors. For example, the droop detection latency may be ½ the system clock cycle, as the droop-detection circuit internally generates a 2× frequency clock using the system clock and generates the error signal within one system clock cycle. This enables early detection before a voltage drop affects any other part of the circuit.

In particular embodiments, The droop detection circuit allows fine-tuning of an early-error detection window by shifting clock phases between the launching flop and capture flop. This allows post-manufacturing calibration of the detection window and further helps to ensure droop impact is not seen by any other part of the circuit design.

In particular embodiments, the droop detection circuit generates a simple binary error signal that can be used by the droop mitigation circuit, which makes it easier to architect and integrate the droop detection circuit with other circuits. Examples of droop mitigation include, for example, (1) a charge-injection module to boost the voltage when the anticipated droop occurs, or (2) a clock-frequency scaling module to lengthen the clock frequency beyond the voltage droop so that timing failures won't occur.

Particular embodiments of a voltage droop monitor comprise an error detection circuit comprising a flip-flop, a latch, and a comparator (e.g., XOR gate) configured to compare a first output of the flip-flop and a second output of the latch. The voltage droop monitor further comprises a clock generator configured to generate a flip-flop clock signal for the flip-flop and a latch clock signal for the latch based on a system clock signal, wherein the flip-flop clock signal and the latch clock signal are inverted and time-shifted with respect to each other, and wherein a triggering edge of the flip-flop clock signal is configured to occur after a termination of a triggering level of the latch clock signal. The voltage droop monitor further comprises a pulse generator circuit configured to generate a series of pulses. The voltage droop monitor further comprises a data path connecting an output of the pulse generator circuit to inputs of the flip-flop and the latch, the data path comprising one or more timing delay components. An output of the comparator indicates whether a voltage droop is detected.

In particular embodiments of the voltage droop monitor, the comparator is configured to indicate that a voltage droop is detected when the first output of the flip-flop and the second output of the latch are different.

In particular embodiments of the voltage droop monitor, the triggering edge of the flip-flop clock signal and the termination of the triggering level of the latch clock signal define an error detection window.

In particular embodiments of the voltage droop monitor, the error detection circuit is configured to detect a voltage droop when a pulse received from the data path transitions from a first value to a second value within the error detection window.

In particular embodiments of the voltage droop monitor, the triggering edge of the flip-flop clock signal is a rising edge and the triggering level of the latch clock signal is a high clock signal.

In particular embodiments of the voltage droop monitor, a timing delay caused by the one or more timing delay components is inversely proportional to a voltage level supplied to the voltage droop monitor.

In particular embodiments of the voltage droop monitor, the one or more timing delay components include a plurality of timing delay components (e.g., inverters).

In particular embodiments, the voltage droop monitor further comprises a first mux configured to select from respective outputs of the plurality of timing delay components.

In particular embodiments of the voltage droop monitor, the pulse generator circuit operates based on the flip-flop clock signal.

In particular embodiments of the voltage droop monitor, the pulse generator circuit comprises a second flip-flop, wherein an input of the second flip-flop is configured to receive an output of the second flip-flop.

In particular embodiments of the voltage droop monitor, the clock generator comprises a series of second timing delay components, and wherein the flip-flop clock signal is generated using a first number of the second timing delay components, and the latch clock signal is generated using a second number of the second timing delay components. In particular embodiments of the voltage droop monitor, the first number and second number are different. In particular embodiments, a difference between the first number and the second number affects a magnitude of an error detection window used by the error detection circuit to detect voltage droop.

In particular embodiments of the voltage droop monitor, the clock generator comprises: a series of second timing delay components; a first mux configured to select outputs from odd timing delay components in the series of second timing delay components, wherein the latch clock signal is an output of the first mux; and a second mux configured to select outputs from even timing delay components in the series of second timing delay components, wherein the flip-flop clock signal is an output of the second mux.

In particular embodiments of the voltage droop monitor, the triggering level of the latch clock signal define a timing window, and wherein the error detection circuit is configured to determine that no error occurs when a pulse generated by the pulse generator circuit transitions from a first value to a second value within the timing window.

In particular embodiments of the voltage droop monitor, an error signal generated by the error detection circuit is configured to trigger a voltage increase.

In particular embodiments of the voltage droop monitor, an error signal generated by the error detection circuit is configured to trigger a lengthening of the system clock.

In particular embodiments, a voltage droop monitor comprises an error detection circuit comprising a flip-flop and a latch. The voltage droop monitor further comprises a clock generator configured to generate a flip-flop clock signal for the flip-flop and a latch clock signal for the latch based on a system clock signal, wherein the flip-flop clock signal and the latch clock signal are inverted and time-shifted with respect to each other, and wherein a triggering edge of the flip-flop clock signal is configured to occur after a termination of a triggering level of the latch clock signal. The triggering edge of the flip-flop clock signal and the termination of the triggering level of the latch clock signal define an error detection window. The error detection circuit is configured to detect a voltage droop when a pulse transitions from a first value to a second value within the error detection window.

In particular embodiments of the voltage droop monitor, the clock generator comprises: a series of second timing delay components; a first mux configured to select outputs from odd timing delay components in the series of second timing delay components, wherein the latch clock signal is an output of the first mux; and a second mux configured to select outputs from even timing delay components in the series of second timing delay components, wherein the flip-flop clock signal is an output of the second mux.

In particular embodiments, a voltage droop monitor performs the steps of: generating, based on a system clock signal, a flip-flop clock signal for a flip-flop and a latch clock signal for a latch, wherein the flip-flop clock signal and the latch clock signal are inverted and time-shifted with respect to each other, and wherein a triggering edge of the flip-flop clock signal is configured to occur after a termination of a triggering level of the latch clock signal; generating a pulse; transmitting the pulse to the flip-flop and the latch through a data path comprising one or more timing delay components; detecting, using the flip-flop and the latch, that a transition of the pulse from a first value to a second value occurred within an error detection window defined by the triggering edge of the flip-flop clock signal and the termination of the triggering level of the latch clock signal; and outputting a signal indicating that a voltage droop is detected.

The embodiments disclosed herein are only examples, and the scope of this disclosure is not limited to them. Particular embodiments may include all, some, or none of the components, elements, features, functions, operations, or steps of the embodiments disclosed herein. Embodiments according to the invention are in particular disclosed in the attached claims directed to a method, a storage medium, a system, and a computer program product, wherein any feature mentioned in one claim category, e.g. method, can be claimed in another claim category, e.g. system, as well. The dependencies or references back in the attached claims are chosen for formal reasons only. However, any subject matter resulting from a deliberate reference back to any previous claims (in particular multiple dependencies) can be claimed as well, so that any combination of claims and the features thereof are disclosed and can be claimed regardless of the dependencies chosen in the attached claims. The subject matter which can be claimed comprises not only the combinations of features as set out in the attached claims but also any other combination of features in the claims, wherein each feature mentioned in the claims can be combined with any other feature or combination of other features in the claims. Furthermore, any of the embodiments and features described or depicted herein can be claimed in a separate claim and/or in any combination with any embodiment or feature described or depicted herein or with any of the features of the attached claims.

### BRIEF DESCRIPTION OF THE DRAWINGS

FIG. 1 illustrates an example voltage diagram in the event of a voltage droop.

FIG. 2 illustrates an example circuit of a voltage droop monitor 200, according to particular embodiments.

FIG. 3A and FIG. 3B illustrate timing diagrams of clock signals used in the voltage droop monitor circuit, according to particular embodiments.

FIG. 4 illustrates an example method for detecting voltage droop, according to particular embodiments.

FIG. 5 illustrates an example computer system.

### DESCRIPTION OF EXAMPLE EMBODIMENTS

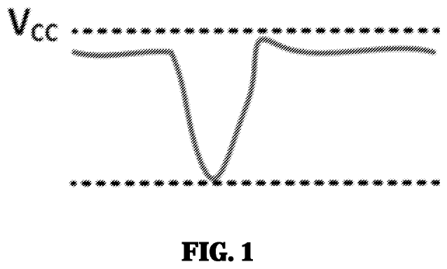

Voltage droop is a common phenomenon in integrated circuits. For example, when a system is idle, current consumption may be only a few milliamps. When the system begins processing instruction or data, however, a large rush of current may pass through. So within a few nanoseconds, current consumption could increase from a few milliamps to one ampere, resulting in a large delta. Since resistance in the circuit is generally fixed, a large spike in current would result in a sudden drop in voltage on the power supply rail, according to Ohm's law (V=IR). FIG. 1 illustrates an example voltage diagram in the event of a voltage droop. The voltage will drop for a short amount of time and slowly recover to reach a steady state. The voltage drop could cause failure in certain digital circuits that require more voltage than the voltage available during a droop, and this failure could be manifested in timing failures.

Existing solutions to handle voltage droops are to build in a voltage guard band or buffer to provide a margin of voltage to compensate for droops. For example, if a 50 millivolt drop is anticipated during a voltage droop, a system that could otherwise operate at 600 millivolts would instead operate at 650 millivolts. This way, even if the voltage drops by 50 millivolts, the system would still have 600 millivolts to support the circuits. The problem is that voltage droops occur seldomly (e.g., 5% of the time), but the additional voltage buffer needs to operate 100% of the time. The extra voltage results in a significant amount of waste, because it increases leakage and higher dynamic power dissipation.

Embodiments described herein provide a voltage droop detection circuit that enables the overall system to operate without adding a voltage guard band/margin for voltage droops. Using the aforementioned example, this means that the system could operate at 600 millivolts instead of 650 millivolts. The voltage-droop monitor would detect the droop and send an error signal to trigger any suitable mitigating modules. For example, an additional voltage may be supplied and/or the clock frequency could be relaxed. The moment clock frequency goes down, the time period of the clock will increase, which means the system would have more margin to satisfy setup time violations that may be caused by a voltage-droop event.

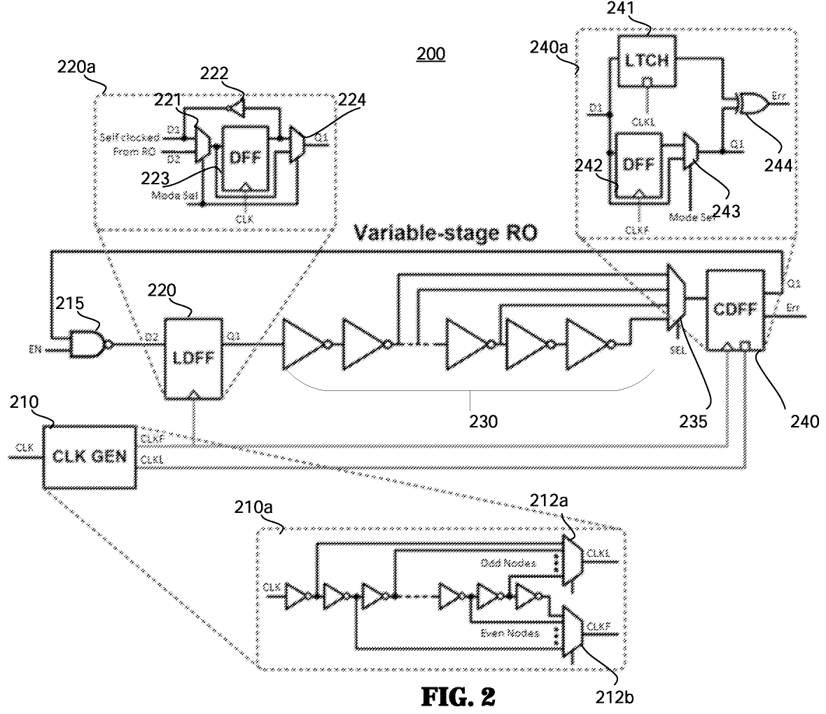

FIG. 2 illustrates an example circuit of a voltage droop monitor 200, according to particular embodiments. The voltage-droop monitor needs to detect a voltage-drop event before any other part of the circuit design sees that voltage drop. Otherwise, if the voltage-droop monitor detects it late, then there is no point because the drop would have already caused errors and timing failures. To enable early detection, the voltage-droop monitor has a lock generator 210 (CLK GEN) that is configured to generate a faster clock frequency (e.g., 2 times, 3 times, 5 times the system clock, for example). The clock generator 210 takes as input the system clock signal (CLK) and outputs two clock signals, CLKF and CLKL, each with a higher frequency than the system clock signal. For example, if the system clock is running at 500 mHz, the clock generator 210 would generate, e.g., 1 gHz clock signals for the voltage-droop circuit 200.

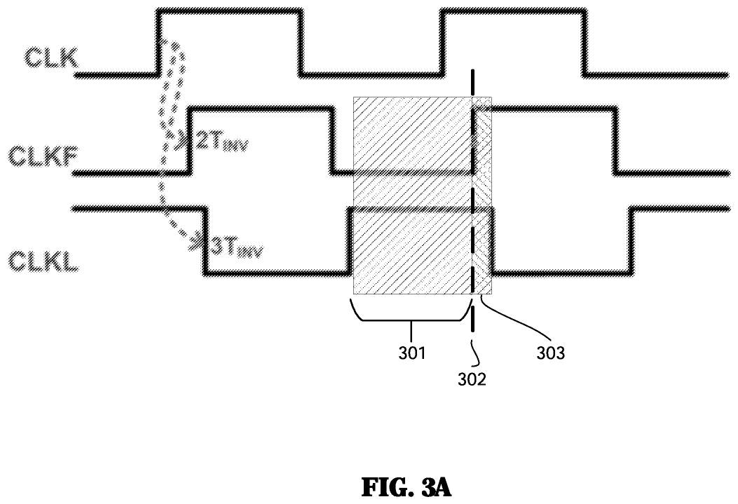

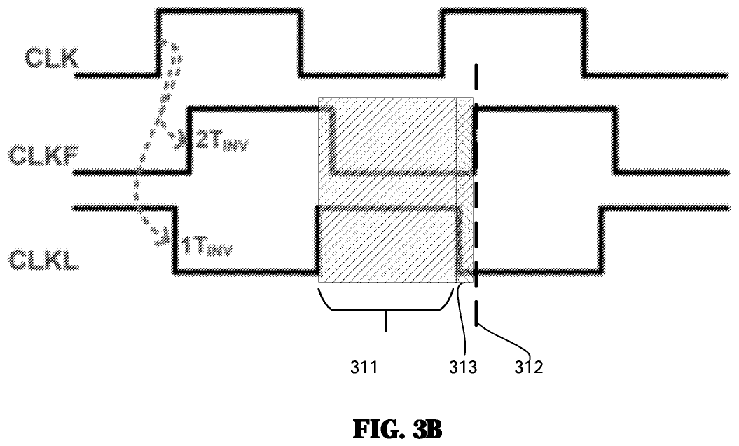

As shown in the zoomed-in portion of CLK GEN 210a, a series of inverters (which could be any other suitable type of timing delay component, such as gates or transistors, that would cause a slight signal delay) are tapped out to a mux 212a for the CLKL output and another mux 212b for the CLKF output. The series of inverters create a timing delay path for the CLK signal. The series of inverters include odd inverters (e.g., the 1^{st}, 3^{rd}, 5^{th}, etc. inverters in the series) and even inverters (e.g., the 2^{nd}, 4^{th}, 6^{th}, etc. inverters in the series). The inverters/gates/transistors used in the timing delay path may be less sensitive to voltage droop as compared to those used in, e.g., the data path 230, which will be described in further detail below. In particular embodiments, the odd nodes—which are the outputs of corresponding odd inverters—may be connected to the CLKL mux 212a. The even nodes—which are the outputs of corresponding even inverters—may be connected to the CLKF mux 212b. In this manner, the latch clock CLKL and the flip flop clock CLKF are roughly phase shifted by 180 degrees so they are generally opposite of each other with a slight timing offset. This relationship between CLKL and CLKF is illustrated in the timing diagram shown in FIG. 3A and FIG. 3B. In the example shown in FIG. 3A, CLKF corresponds to the output of the second inverter in the series of inverters in CLK GEN 210a, and CLKL corresponds to the output of the third inverter in the series of inverters in CLK GEN 210a. Because the third inverter introduces additional delay, the CLKL signal is slightly delayed relative to CLKF. In FIG. 3B, CLKF corresponds to the output of the second inverter in the series of inverters in CLK GEN 210a, and CLKL corresponds to the output of the first inverter in the series of inverters in CLK GEN 210a. Because the second inverter introduces additional delay, the CLKF signal is slightly delayed relative to CLKL. The slight timing offset creates an error detection window for detecting delays caused by voltage droop. Additional details will be further described below.

The clock generator 210a may be configured at design time or runtime to generate different clock frequencies and offsets. Using the muxes 212a-b, a system designer may choose the output of any of the odd inverters to be output as CLKL and choose the output of any of the even inverters to be output as CLKF. For example, in one configuration, the output of the third odd inverter (which corresponds to the fifth inverter overall) may be selected as the output CLKL signal, and the third even inverter (which corresponds to the sixth inverter overall) may be selected as the output CLKF signal. In another embodiment, the output of the odd inverters may instead be connected to CLKF and the output of the even inverters may instead be connected to CLKL. The gap between the selected node for CLKL and the node selected for CLKF affects the shift between the clock signals (larger the gap between the nodes results in a larger shift, and vice versa). For example, having CLKL be the output of the third odd inverter and CLKF be the output of the ninth even inverter would result in a larger shift between the clock signals. In addition to the magnitude of the time shift, the relative timing sequence between the CLKL and CLKF signals may also be customized. Since inverters cause timing delays, a datapath with more inverters would introduce more delay. This design provides the flexibility of choosing any one of these intermediate nodes to be passed as the latch clock and the flop clock. So even after the silicon is built, the timing of these clocks could be configured. The shift between these two clocks affects the early error detection window, which will be described in further detail below.

In the circuit diagram shown in FIG. 2, a pulse generator circuit, LDFF 220, is configured to launch alternating pulses through a data path 230 to an error detection circuit, CDFF 240. Thanks to the faster clock cycles of CLKF and CLKL relative to the system clock CLK, LDFF 220 and CDFF 240 could detect a drop in voltage before it impacts the system overall.

When enabled, LDFF 220 will generate an alternating pulse at the clock cycle of CLKF. An output pulse generated by LDFF 220 is sent through data path 230, which includes a series of inverters in the embodiment shown. The inverters introduce a signal delay when the voltage is too low. Instead of inverters, other types of timing-delay circuit components that are sensitive to voltage drops could also be used, meaning that the timing delay caused by such timing-delay circuit components is inversely proportional to voltage. For example, the timing delay caused by the timing-delay circuit components in data path 230 would be greater when the voltage drops lower. The output of each timing-delay component in the data path 230 is selectable via mux 235. In particular embodiments, there may be multiple series of different types of circuit elements to choose from via the mux 235. The amount of desired delay or sensitivity to voltage drop is therefore configurable through mux 235. For example, if more delay is desired, the mux 235 could be instructed to select more timing-delay components (e.g., the output of the eighth inverter could be selected instead of the third inverter). The output of the mux 235 is then provided as the D1 data input to CDFF 240.

When enabled, CDFF 240 would detect signal delays caused by the inverters in the data path 230 due to a voltage drop. CDFF 240 takes the output of mux 235, which selects the output of a particular inverter in data path 230. In particular embodiments, CDFF 240 includes a latch LTCH 241 and D-flip-flop DFF 242. The LTCH 241 and DFF 242 both receive the same input D1 from mux 235 but are controlled by different clocks, CLKL and CLKF, respectively. As previously discussed, these clocks are opposite or inverted relative to each other and have a slight timing shift. The LTCH 241 is configured to be level triggered, meaning that the data value on its input from D1 is the output of the latch's 241 Q output when the CLKL value is high, and the last value of D1 before the CLKL value becomes low is retained while the CLKL value remains low. The LTCH 241 is “transparent” during the period when the latch's output Q reflects the input D1. This transparent time is shown as the timing window in FIG. 3.

DFF 242, on the other hand, is edge-triggered. In particular embodiments, DFF 242 is positive-edge triggered, which means that it retains the data on input D1 when CLKF transitions from 0 to 1. It should be understood by those skilled in the art that a negative-edge triggered flip flop could also be used without deviating from the concepts described herein.

When CDFF 240 is enabled, the output from LTCH 241 and DFF 242 are compared using an XOR gate 244. When the outputs from LTCH 241 and DFF 242 are the same, XOR gate 244 would output 0, indicating that there is no error. However, when the outputs from LTCH 241 and DFF 242 are different, XRO gate 244 would output 1, indicating that an error has been detected.

The aforementioned error-detection circuit could be enabled or disabled. When disabled, the EN input of NAND gate 215 would be 0, which means the output of the NAND gate 215 would be 1 and be passed as input D2 to LDFF 220. Referring to the detailed diagram of LDFF 220a, the D2 input is one of two inputs to mux 221. In this particular example, it is coupled to the 1 input of mux 221 (i.e., D2 would be selected when Mode Sel is 1). D2 is also used as the selection input, Mode Sel, for mux 221. So when the error detection circuit is disabled, Mode Sel would be 1, causing the mux 221 to select D2 as its output. The output of mux 221 is sent to the input of DFF 223 and the 1 input of mux 224. Since Mode Sel is 1, mux 224 would select the output of mux 221 as its output Q1. In effect, the output of DFF 223 would be ignored in this case.

The output Q1 of LDFF 220 would travel through datapath 230 and become input D1 for CDFF 240. Since Mode Sel is 1 when error detection is disabled, mux 243 would select D1 as its output, which in turn would be the Q1 output of CDFF. In addition, Q1, which reflects the D1 input, would be compared to the latched D1 value from LTCH 241. Since the values would be the same, XOR 244 would always output 0, indicating that no error has occurred. The error detection circuits, including LTCH 241 and DFF 242, are bypassed.

When error detection is enabled, NAND 215 would inverse the Q1 output of CDFF 240. When error detection is enabled, Mode Sel for mux 221 would be 0, causing mux 221 to select D1, which is the output of DFF 223 after being inverted by inverter 222. So if DFF 223 had the value 1 stored, the new D1 would be 0; if DFF 223 had the value 0 stored, the new D1 would be 1. The D1 value would be sent to DFF 223. Since Mode Sel is 0 in this scenario, mux 224 would select the output of DFF 223 as the Q1 output of LDFF 220a. In this manner, when error detection is enabled, LDFF 220 would output a series of inverted pulses.

The pulse would traverse through data path 230 and become the input D1 of CDFF 240a. Since Mode Sel is 0, mux 243 would select the output of DFF 242 as its output Q1. Therefore, the XOR gate 244 would compare the output of LTCH 241 and DFF 242 and detect whether the signals are the same or different. If they're the same, XOR 244 would output 0, indicating that no error has occurred. If they're different, XOR 244 would output 1, signifying an error.

FIG. 3B illustrates a different configuration where voltage droops can be detected within the detection window. Here, the data path selected for CLKF includes more timing-delay inverters (e.g., 2 inverters) than the inverters (e.g., 1 inverter) in the data path selected for CLKL. This results in the rising edge 312 of CLKF occurring after the falling edge of CLKL, as shown. The early error detection window 313 is shown to be between the downward edge of CLKL and the subsequent rising edge 312 of CLKF. A timing window 311 is defined to be between the rising edge of CLKL and the beginning of the early error detection window 313. If D1 input of CDFF changes during the timing window 311, CDFF 240 would indicate that no error or significant voltage droop has occurred. On the other hand, if D1 input of CDFF 240 changes during the early error detection window 313, the CDFF 240 circuit would register an error.

This is best illustrated with an example. Let's assume that D1 transitions from 1 to 0 (or 1 to 0) at some point within the timing window 311. The output of the DFF 242 in CDFF 240 after the rising edge 312 of CLKF would be 0 because the risking edge 312 of CLKF would cause DFF 242 to capture the final value of D1 during the timing window 311, which is 0 in this example. The LTCH 241 would register the D1 value 0 because D1 transitioned to 0 during the timing window 311 while CLKL is high. The 0 value would be retained by LTCH 241 after CLKL goes low. So after the rising edge 312 of CLKF, the output of LTCH 241 would also be 0. Because the values from the latch and the flop are the same, CDFF 240 will output no error, which indicates that the transition of D1 occurred during the acceptable range defined by the timing window 311.

Now let's assume the data transition of D1 occurred in the early error detection window 313 instead. Again, in this example, D1's value changed from 1 to 0. After the rising edge 312 of CLKF, the DFF 242 would capture and output the final value of D1 during the error detection window 313, which was 0 in this example, because the DFF 242 captured and retained D1's value after the rising edge. The LTCH 241, however, did not capture the final value of D1 because the transition occurred outside of the LTCH 241's data-capture window. Stated differently, the value of D1 was 1 when CLKL was high, and D1 did not transition to 0 until CLKL became low. As such, the output of the LTCH 241 after the dotted line 312 would still be the original value of D1, which was 1 in this example. Because the values of DFF 242 and LTCH 241 are different, the CDFF circuit would output an error, indicating that the data transition on D1 did not occur until the early error detection window 313, signifying a timing delay caused by a voltage drop. The relative timing of CLKF and CLKL shown in FIG. 3B was arranged such that a detection window 313 was defined after LTCH 241 no longer registered new values (its CLKL signal was low) while the DFF 242 could still capture D1's transition during window 313 (CLKF's rising edge 312 is at the end of the window 313). In other words, LTCH 241 would store the original value of D1, and any changes to D1 during the detection window 313 after the CLKL goes low would be captured by DFF 242's rising edge 312. This allows the circuit to capture changes that occur within window 313.

Now returning to FIG. 3A, which illustrates a timing diagram of a configuration where ambiguity exists as to when D1 transitions. The particular circuit previously described would not properly detect a significant timing delay caused by a voltage droop. Since CLKF's rising edge 302 occurred before the window 303, DFF 242 would not capture any changes in D1 that occurred during window 303. Since CLKL remained high during the window 303, LTCH 241 would be unable to retain the original value of D1 since it would capture the new value of D1 when D1 transitioned from 1 to 0 during the window 303.

During configuration/calibration, the early error detection window 313 could first be adjusted using the muxes 212a-b in CLK GEN 210a to shift CLKF and CLKL relative to each other. Then, the appropriate output node in the data path 230 between LDFF 220 and CDFF 240 may be selected using mux 235 such that the D1 data transition would normally occur during the timing window 311 when voltage is at an acceptable level. When the voltage drops to an unacceptable level, the D1 transition would occur during the error detection window 312. The circuit 200 would then be able to detect such an event and generate an error signal for whatever mitigating mechanism is used (e.g., boosting the voltage or lengthening the clock cycle).

Benefits of this voltage droop detector include, e.g., (1) closed loop operation for delay calibration and RO-based measurement, (2) open loop operation to mimic critical path and use LDFF and CDFF to capture timing error, (3) CLK GEN block calibrates capture flop and latch clocks to fine-tune the early error detection window, and (4) CLK GEN block has a frequency doubler to double the core clock frequency (for detecting early failures).

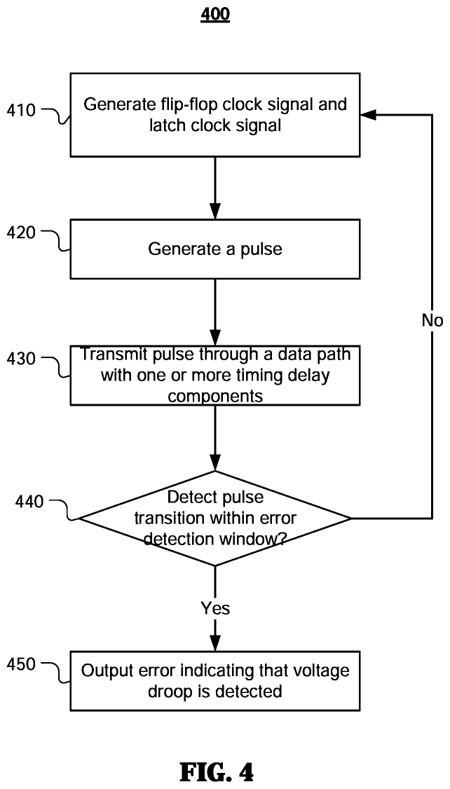

FIG. 4 illustrates an example method 400 for detecting voltage droop, according to particular embodiments. At step 410, a voltage droop monitor may generate, based on a system clock signal, a flip-flop clock signal for a flip-flop and a latch clock signal for a latch, wherein the flip-flop clock signal and the latch clock signal are inverted and time-shifted with respect to each other, and wherein a triggering edge of the flip-flop clock signal is configured to occur after a termination of a triggering level of the latch clock signal. At step 420, the voltage droop monitor may generate a pulse. At step 430, the voltage droop monitor may transmit the pulse to the flip-flop and the latch through a data path comprising one or more timing delay components (e.g., inverters). At step 440, the voltage droop monitor may detect, using the flip-flop and the latch, that a transition of the pulse from a first value to a second value occurred within an error detection window defined by the triggering edge of the flip-flop clock signal and the termination of the triggering level of the latch clock signal. At step 450, if a transition is detected within the error detection window, the voltage droop monitor may output a signal indicating that a voltage droop is detected.

Particular embodiments may repeat one or more steps of the method of FIG. 4, where appropriate. Although this disclosure describes and illustrates particular steps of the method of FIG. 4 as occurring in a particular order, this disclosure contemplates any suitable steps of the method of FIG. 4 occurring in any suitable order. Furthermore, although this disclosure describes and illustrates particular components, devices, or systems carrying out particular steps of the method of FIG. 4, this disclosure contemplates any suitable combination of any suitable components, devices, or systems carrying out any suitable steps of the method of FIG. 4.

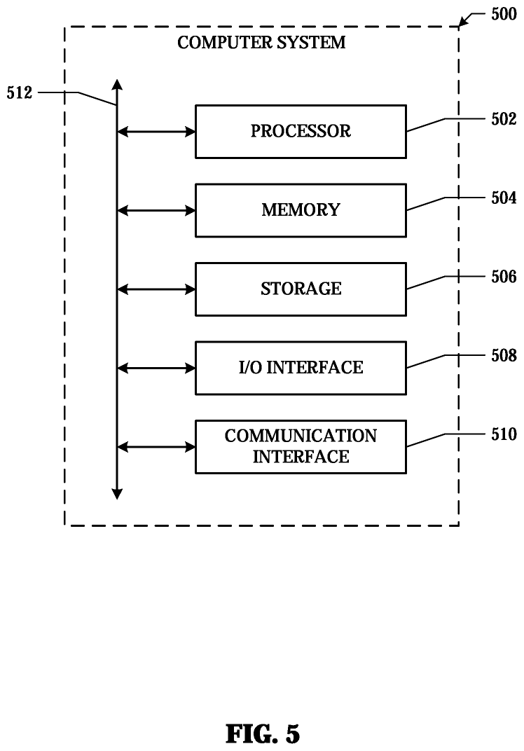

FIG. 5 illustrates an example computer system 500 that may employ the voltage droop detection mechanism described herein. In particular embodiments, one or more computer systems 500 perform one or more steps of one or more methods described or illustrated herein. In particular embodiments, one or more computer systems 500 provide the functionality described or illustrated herein. In particular embodiments, software running on one or more computer systems 500 performs one or more steps of one or more methods described or illustrated herein or provides functionality described or illustrated herein. Particular embodiments include one or more portions of one or more computer systems 500. Herein, reference to a computer system may encompass a computing device, and vice versa, where appropriate. Moreover, reference to a computer system may encompass one or more computer systems, where appropriate.

This disclosure contemplates any suitable number of computer systems 500. This disclosure contemplates computer system 500 taking any suitable physical form. As example and not by way of limitation, computer system 500 may be an embedded computer system, a system-on-chip (SOC), a single-board computer system (SBC) (such as, for example, a computer-on-module (COM) or system-on-module (SOM)), a desktop computer system, a laptop or notebook computer system, an interactive kiosk, a mainframe, a mesh of computer systems, a mobile telephone, a personal digital assistant (PDA), a server, a tablet computer system, an augmented/virtual reality device, or a combination of two or more of these. Where appropriate, computer system 500 may include one or more computer systems 500; be unitary or distributed; span multiple locations; span multiple machines; span multiple data centers; or reside in a cloud, which may include one or more cloud components in one or more networks. Where appropriate, one or more computer systems 500 may perform without substantial spatial or temporal limitation one or more steps of one or more methods described or illustrated herein. As an example and not by way of limitation, one or more computer systems 500 may perform in real-time or in batch mode one or more steps of one or more methods described or illustrated herein. One or more computer systems 500 may perform at different times or at different locations one or more steps of one or more methods described or illustrated herein, where appropriate.

In particular embodiments, computer system 500 includes a processor 502, memory 504, storage 506, an input/output (I/O) interface 508, a communication interface 510, and a bus 512. Although this disclosure describes and illustrates a particular computer system having a particular number of particular components in a particular arrangement, this disclosure contemplates any suitable computer system having any suitable number of any suitable components in any suitable arrangement.

In particular embodiments, processor 502 includes hardware for executing instructions, such as those making up a computer program. As an example and not by way of limitation, to execute instructions, processor 502 may retrieve (or fetch) the instructions from an internal register, an internal cache, memory 504, or storage 506; decode and execute them; and then write one or more results to an internal register, an internal cache, memory 504, or storage 506. In particular embodiments, processor 502 may include one or more internal caches for data, instructions, or addresses. This disclosure contemplates processor 502 including any suitable number of any suitable internal caches, where appropriate. As an example and not by way of limitation, processor 502 may include one or more instruction caches, one or more data caches, and one or more translation lookaside buffers (TLBs). Instructions in the instruction caches may be copies of instructions in memory 504 or storage 506, and the instruction caches may speed up retrieval of those instructions by processor 502. Data in the data caches may be copies of data in memory 504 or storage 506 for instructions executing at processor 502 to operate on; the results of previous instructions executed at processor 502 for access by subsequent instructions executing at processor 502 or for writing to memory 504 or storage 506; or other suitable data. The data caches may speed up read or write operations by processor 502. The TLBs may speed up a virtual-address translation for processor 502. In particular embodiments, processor 502 may include one or more internal registers for data, instructions, or addresses. This disclosure contemplates processor 502 including any suitable number of suitable internal registers, where appropriate. Where appropriate, processor 502 may include one or more arithmetic logic units (ALUs); be a multi-core processor; or include one or more processors 502. Although this disclosure describes and illustrates a particular processor, this disclosure contemplates any suitable processor.

In particular embodiments, memory 504 includes main memory for storing instructions for processor 502 to execute or data for processor 502 to operate on. As an example and not by way of limitation, computer system 500 may load instructions from storage 506 or another source (for example, another computer system 500) to memory 504. Processor 502 may then load the instructions from memory 504 to an internal register or internal cache. To execute the instructions, processor 502 may retrieve the instructions from the internal register or internal cache and decode them. During or after the execution of the instructions, processor 502 may write one or more results (which may be intermediate or final results) to the internal register or internal cache. Processor 502 may then write one or more of those results to memory 504. In particular embodiments, processor 502 executes only instructions in one or more internal registers or internal caches or in memory 504 (as opposed to storage 506 or elsewhere) and operates only on data in one or more internal registers or internal caches or in memory 504 (as opposed to storage 506 or elsewhere). One or more memory buses (which may each include an address bus and a data bus) may couple processor 502 to memory 504. Bus 512 may include one or more memory buses, as described below. In particular embodiments, one or more memory management units (MMUs) reside between processor 502 and memory 504 and facilitate access to memory 504 requested by processor 502. In particular embodiments, memory 504 includes random access memory (RAM). This RAM may be volatile memory, where appropriate. Where appropriate, this RAM may be dynamic RAM (DRAM) or static RAM (SRAM). Moreover, where appropriate, this RAM may be single-ported or multi-ported RAM. This disclosure contemplates any suitable RAM. Memory 504 may include one or more memories 504, where appropriate. Although this disclosure describes and illustrates particular memory, this disclosure contemplates any suitable memory.

In particular embodiments, storage 506 includes mass storage for data or instructions. As an example and not by way of limitation, storage 506 may include a hard disk drive (HDD), a floppy disk drive, flash memory, an optical disc, a magneto-optical disc, magnetic tape, or a Universal Serial Bus (USB) drive or a combination of two or more of these. Storage 506 may include removable or non-removable (or fixed) media, where appropriate. Storage 506 may be internal or external to computer system 500, where appropriate. In particular embodiments, storage 506 is a non-volatile, solid-state memory. In particular embodiments, storage 506 includes read-only memory (ROM). Where appropriate, this ROM may be mask-programmed ROM, programmable ROM (PROM), erasable PROM (EPROM), electrically erasable PROM (EEPROM), electrically alterable ROM (EAROM), flash memory, or a combination of two or more of these. This disclosure contemplates mass storage 506 taking any suitable physical form. Storage 506 may include one or more storage control units facilitating communication between processor 502 and storage 506, where appropriate. Where appropriate, storage 506 may include one or more storage 506. Although this disclosure describes and illustrates particular storage, this disclosure contemplates any suitable storage.

In particular embodiments, I/O interface 508 includes hardware, software, or both, providing one or more interfaces for communication between computer system 500 and one or more I/O devices. Computer system 500 may include one or more of these I/O devices, where appropriate. One or more of these I/O devices may enable communication between a person and computer system 500. As an example and not by way of limitation, an I/O device may include a keyboard, keypad, microphone, monitor, mouse, printer, scanner, speaker, still camera, stylus, tablet, touch screen, trackball, video camera, another suitable I/O device or a combination of two or more of these. An I/O device may include one or more sensors. This disclosure contemplates any suitable I/O devices and any suitable I/O interfaces 508 for them. Where appropriate, I/O interface 508 may include one or more device or software drivers enabling processor 502 to drive one or more of these I/O devices. I/O interface 508 may include one or more I/O interfaces 508, where appropriate. Although this disclosure describes and illustrates a particular I/O interface, this disclosure contemplates any suitable I/O interface.

In particular embodiments, communication interface 510 includes hardware, software, or both providing one or more interfaces for communication (such as, for example, packet-based communication) between computer system 500 and one or more other computer systems 500 or one or more networks. As an example and not by way of limitation, communication interface 510 may include a network interface controller (NIC) or network adapter for communicating with an Ethernet or other wire-based network or a wireless NIC (WNIC) or wireless adapter for communicating with a wireless network, such as a WI-FI network. This disclosure contemplates any suitable network and any suitable communication interface 510 for it. As an example and not by way of limitation, computer system 500 may communicate with an ad hoc network, a personal area network (PAN), a local area network (LAN), a wide area network (WAN), a metropolitan area network (MAN), or one or more portions of the Internet or a combination of two or more of these. One or more portions of one or more of these networks may be wired or wireless. As an example, computer system 500 may communicate with a wireless PAN (WPAN) (such as, for example, a BLUETOOTH WPAN), a WI-FI network, a WI-MAX network, a cellular telephone network (such as, for example, a Global System for Mobile Communications (GSM) network), or other suitable wireless network or a combination of two or more of these. Computer system 500 may include any suitable communication interface 510 for any of these networks, where appropriate. Communication interface 510 may include one or more communication interfaces 510, where appropriate. Although this disclosure describes and illustrates a particular communication interface, this disclosure contemplates any suitable communication interface.

In particular embodiments, bus 512 includes hardware, software, or both coupling components of computer system 500 to each other. As an example and not by way of limitation, bus 512 may include an Accelerated Graphics Port (AGP) or other graphics bus, an Enhanced Industry Standard Architecture (EISA) bus, a front-side bus (FSB), a HYPERTRANSPORT (HT) interconnect, an Industry Standard Architecture (ISA) bus, an INFINIBAND interconnect, a low-pin-count (LPC) bus, a memory bus, a Micro Channel Architecture (MCA) bus, a Peripheral Component Interconnect (PCI) bus, a PCI-Express (PCIe) bus, a serial advanced technology attachment (SATA) bus, a Video Electronics Standards Association local (VLB) bus, or another suitable bus or a combination of two or more of these. Bus 512 may include one or more buses 512, where appropriate. Although this disclosure describes and illustrates a particular bus, this disclosure contemplates any suitable bus or interconnect.

Herein, a computer-readable non-transitory storage medium or media may include one or more semiconductor-based or other integrated circuits (ICs) (such, as for example, field-programmable gate arrays (FPGAs) or application-specific ICs (ASICs)), hard disk drives (HDDs), hybrid hard drives (HHDs), optical discs, optical disc drives (ODDs), magneto-optical discs, magneto-optical drives, floppy diskettes, floppy disk drives (FDDs), magnetic tapes, solid-state drives (SSDs), RAM-drives, SECURE DIGITAL cards or drives, any other suitable computer-readable non-transitory storage media, or any suitable combination of two or more of these, where appropriate. A computer-readable non-transitory storage medium may be volatile, non-volatile, or a combination of volatile and non-volatile, where appropriate.

Herein, “or” is inclusive and not exclusive, unless expressly indicated otherwise or indicated otherwise by context. Therefore, herein, “A or B” means “A, B, or both,” unless expressly indicated otherwise or indicated otherwise by context. Moreover, “and” is both joint and several, unless expressly indicated otherwise or indicated otherwise by context. Therefore, herein, “A and B” means “A and B, jointly or severally,” unless expressly indicated otherwise or indicated otherwise by context.

The scope of this disclosure encompasses all changes, substitutions, variations, alterations, and modifications to the example embodiments described or illustrated herein that a person having ordinary skill in the art would comprehend. The scope of this disclosure is not limited to the example embodiments described or illustrated herein. Moreover, although this disclosure describes and illustrates respective embodiments herein as including particular components, elements, features, functions, operations, or steps, any of these embodiments may include any combination or permutation of any of the components, elements, features, functions, operations, or steps described or illustrated anywhere herein that a person having ordinary skill in the art would comprehend. Furthermore, reference in the appended claims to an apparatus or system or a component of an apparatus or system being adapted to, arranged to, capable of, configured to, enabled to, operable to, or operative to perform a particular function encompasses that apparatus, system, component, whether or not it or that particular function is activated, turned on, or unlocked, as long as that apparatus, system, or component is so adapted, arranged, capable, configured, enabled, operable, or operative. Additionally, although this disclosure describes or illustrates particular embodiments as providing particular advantages, particular embodiments may provide none, some, or all of these advantages.

What is claimed is:

1. A voltage droop monitor, comprising:
an error detection circuit comprising a flip-flop, a latch, and a comparator configured to compare a first output of the flip-flop and a second output of the latch;
a clock generator configured to generate a flip-flop clock signal for the flip-flop and a latch clock signal for the latch based on a system clock signal, wherein the flip-flop clock signal and the latch clock signal are inverted and time-shifted with respect to each other, and wherein a triggering edge of the flip-flop clock signal is configured to occur after a termination of a triggering level of the latch clock signal;
a pulse generator circuit configured to generate a series of pulses; and
a data path connecting an output of the pulse generator circuit to inputs of the flip-flop and the latch, the data path comprising one or more timing delay components;
wherein an output of the comparator indicates whether a voltage droop is detected.

2. The voltage droop monitor of claim 1, wherein the comparator is configured to indicate that a voltage droop is detected when the first output of the flip-flop and the second output of the latch are different.

3. The voltage droop monitor of claim 1, wherein the triggering edge of the flip-flop clock signal and the termination of the triggering level of the latch clock signal define an error detection window.

4. The voltage droop monitor of claim 3, wherein the error detection circuit is configured to detect a voltage droop when a pulse received from the data path transitions from a first value to a second value within the error detection window.

5. The voltage droop monitor of claim 1, wherein the triggering edge of the flip-flop clock signal is a rising edge and the triggering level of the latch clock signal is a high clock signal.

6. The voltage droop monitor of claim 1, wherein a timing delay caused by the one or more timing delay components is inversely proportional to a voltage level supplied to the voltage droop monitor.

7. The voltage droop monitor of claim 1, wherein the one or more timing delay components include a plurality of timing delay components.

8. The voltage droop monitor of claim 7, further comprising:
a first mux configured to select from respective outputs of the plurality of timing delay components.

9. The voltage droop monitor of claim 1, wherein the pulse generator circuit operates based on the flip-flop clock signal.

10. The voltage droop monitor of claim 1, wherein the pulse generator circuit comprises a second flip-flop, wherein an input of the second flip-flop is configured to receive an output of the second flip-flop.

11. The voltage droop monitor of claim 1, wherein the clock generator comprises a series of second timing delay components, and wherein the flip-flop clock signal is generated using a first number of the second timing delay components, and the latch clock signal is generated using a second number of the second timing delay components.

12. The voltage droop monitor of claim 11, wherein the first number and second number are different.

13. The voltage droop monitor of claim 12, wherein a difference between the first number and the second number affects a magnitude of an error detection window used by the error detection circuit to detect voltage droop.

14. The voltage droop monitor of claim 1, wherein the clock generator comprises:
a series of second timing delay components;
a first mux configured to select outputs from odd timing delay components in the series of second timing delay components, wherein the latch clock signal is an output of the first mux; and
a second mux configured to select outputs from even timing delay components in the series of second timing delay components, wherein the flip-flop clock signal is an output of the second mux.

15. The voltage droop monitor of claim 1, wherein the triggering level of the latch clock signal defines a timing window, and wherein the error detection circuit is configured to determine that no error occurs when a pulse generated by the pulse generator circuit transitions from a first value to a second value within the timing window.

16. The voltage droop monitor of claim 1, wherein an error signal generated by the error detection circuit is configured to trigger a voltage increase.

17. The voltage droop monitor of claim 1, wherein an error signal generated by the error detection circuit is configured to trigger a lengthening of the system clock.

18. A voltage droop monitor, comprising:
an error detection circuit comprising a flip-flop and a latch; and
a clock generator configured to generate a flip-flop clock signal for the flip-flop and a latch clock signal for the latch based on a system clock signal, wherein the flip-flop clock signal and the latch clock signal are inverted and time-shifted with respect to each other, and wherein a triggering edge of the flip-flop clock signal is configured to occur after a termination of a triggering level of the latch clock signal;
wherein the triggering edge of the flip-flop clock signal and the termination of the triggering level of the latch clock signal define an error detection window; and
wherein the error detection circuit is configured to detect a voltage droop when a pulse transitions from a first value to a second value within the error detection window.

19. The voltage droop monitor of claim 18, wherein the clock generator comprises:
a series of second timing delay components;
a first mux configured to select outputs from odd timing delay components in the series of second timing delay components, wherein the latch clock signal is an output of the first mux; and
a second mux configured to select outputs from even timing delay components in the series of second timing delay components, wherein the flip-flop clock signal is an output of the second mux.

20. A method comprising:
generating, based on a system clock signal, a flip-flop clock signal for a flip-flop and a latch clock signal for a latch, wherein the flip-flop clock signal and the latch clock signal are inverted and time-shifted with respect to each other, and wherein a triggering edge of the flip-flop clock signal is configured to occur after a termination of a triggering level of the latch clock signal;
generating a pulse;
transmitting the pulse to the flip-flop and the latch through a data path comprising one or more timing delay components;
detecting, using the flip-flop and the latch, that a transition of the pulse from a first value to a second value occurred within an error detection window defined by the triggering edge of the flip-flop clock signal and the termination of the triggering level of the latch clock signal; and
outputting a signal indicating that a voltage droop is detected.
